(19) United States
(12) Patent Application Publication
(10) Pub. No.: US 2011/0249410 A1
(43) Pub. Date: Oct. 13, 2011

(54) CARD HOLDING APPARATUS CAPABLE OF HOLDING CARD-SHAPED ELECTRONIC DEVICE, AND ELECTRONIC EQUIPMENT PROVIDED WITH THE SAME

(75) Inventors: Shinji FUJITA, Osaka (JP); Tetsuya KAWAMOTO, Osaka (JP); Akira IWAMOTO, Osaka (JP)

(73) Assignee: PANASONIC CORPORATION, Osaka (JP)

(21) Appl. No.: 13/075,722

(22) Filed: Mar. 30, 2011

(30) Foreign Application Priority Data
Apr. 9, 2010 (JP) 2010-090633

(51) Int. Cl. H05K 7/00

(52) U.S. Cl. 361/748

(57) ABSTRACT

Due to the presence of a regulating part in the vicinity of a protrusion of a guide member, a card holding apparatus can prevent large deformation of the protrusion even when an excess pressure force in an insertion direction is applied to the expansion card mounted on the card holding apparatus. Thus, when the subsequent expansion cards are mounted, a guide member can be displaced normally in the insertion direction, and a heart-shaped cam mechanism can be operated normally. Therefore, the expansion card can be removed from the card holding apparatus, using the elastic restoring force of a spring.

### BACKGROUND OF THE INVENTION

1. Field of the Invention

The present application relates to a card holding apparatus capable of holding a card-shaped electronic device. The present application relates to electronic equipment provided with the card holding apparatus.

2. Description of Related Art

In recent years, the number of models of notebook computers is increasing, which have slots allowing standardized expansion cards such as a Personal Computer Memory Card Interface Association (PCMCIA) card and an EXPRESS card to be inserted therein or removed therefrom. As such expansion cards, a network card equipped with a connector capable of connecting a network cable such as a LAN cable and a network card equipped with an antenna and a transmission/reception circuit capable of being connected to a wireless LAN are available. The network card capable of connecting a network cable has a thin housing that can be inserted in a slot and a thick housing that cannot be inserted in a slot and has a LAN connector, etc. Further, the network card capable of being connected to a wireless LAN has a thin housing that can be inserted in a slot and a thick housing that cannot be inserted in a slot and has an antenna and a transmission/reception circuit. When any of the network cards is inserted in a predetermined slot of a notebook computer, the thick housing protrudes from the notebook computer.

If a part (thick housing) of the network card protrudes from the notebook computer as described above, when the notebook computer falls to a floor or the like accidentally with the thick housing side directed downwardly in a vertical direction, the network card is subjected to strong impact in an insertion direction thereof.

JP 10(1998)-334976 A discloses a method for protecting a back connector of memory card-shaped equipment with a back connector. JP 2005-197216 A discloses a configuration in which the strength of a card connector is enhanced by providing a side edge member formed of a metal plate material at a card insertion port.

However, when an expansion card inserted in a slot is subjected to impact, an excess load may be applied to a mechanism holding the expansion card inside the slot to deform the mechanism. If the mechanism is deformed, the expansion card cannot be attached or detached normally.

### SUMMARY OF THE INVENTION

Therefore, with the foregoing in mind, it is an object of the present invention to provide a card holding apparatus allowing an expansion card to be attached or detached with respect thereto, including: a guide member capable of being displaced in an insertion direction and a removal direction of the expansion card; a biasing member that biases the guide member in the removal direction of the expansion card, wherein the guide member has a protrusion at a position with which the expansion card is capable of coming into contact, and has a regulating part that is placed on the connector side with respect to the protrusion and regulates a displacement of the protrusion to the connector side.

Electronic equipment disclosed by the present application has a slot allowing an expansion card to be inserted therein or removed therefrom, includes a card holding apparatus that is placed in the slot and allows the expansion card to be attached/detached with respect thereto, wherein the card holding apparatus includes a guide member capable of being displaced in an insertion direction and a removal direction of the expansion card, and a biasing member that biases the guide member in the removal direction of the expansion card, and the guide member has a protrusion at a position with which the expansion card comes into contact, and a regulating part that is placed on the connector side with respect to the protrusion and regulates a displacement of the protrusion on the connector side.

### BRIEF DESCRIPTION OF THE DRAWINGS

FIG. 1 is a perspective view of a notebook computer according to an embodiment of the present invention.

FIG. 2 is a plan view of main portions of the notebook computer according to the embodiment of the present invention.

FIG. 3 is an exploded perspective view of a card holding apparatus.

FIG. 4 is a perspective view of a guide member.

FIG. 5 is a perspective view of a connector.

FIG. 6A is a plan view illustrating an attachment/detachment operation of an expansion card with respect to the card holding apparatus.

FIG. 6B is a plan view illustrating the attachment/detachment operation of the expansion card with respect to the card holding apparatus.

FIG. 6C a plan view illustrating the attachment/detachment operation of the expansion card with respect to the card holding apparatus.

FIG. 7 is a partial perspective view illustrating an engagement state between a connector and a guide member.

### DETAILED DESCRIPTION OF THE EMBODIMENTS

### (Embodiment)

### [1. Configuration of Electronic Equipment]

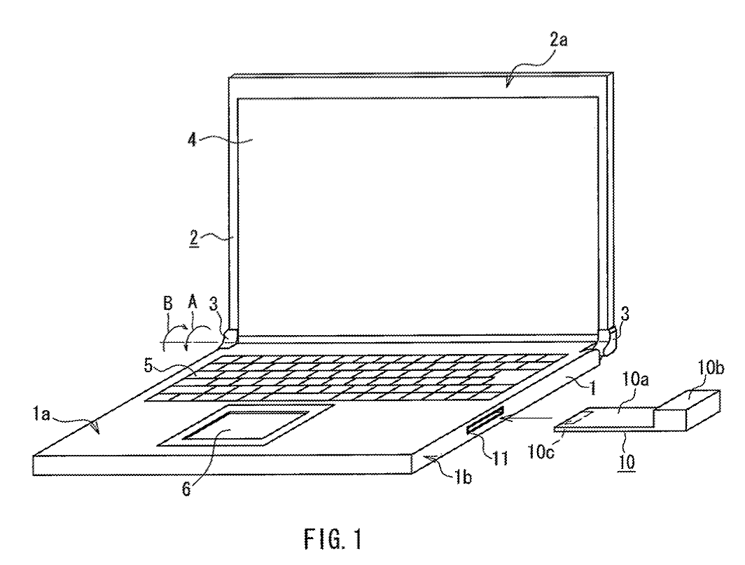

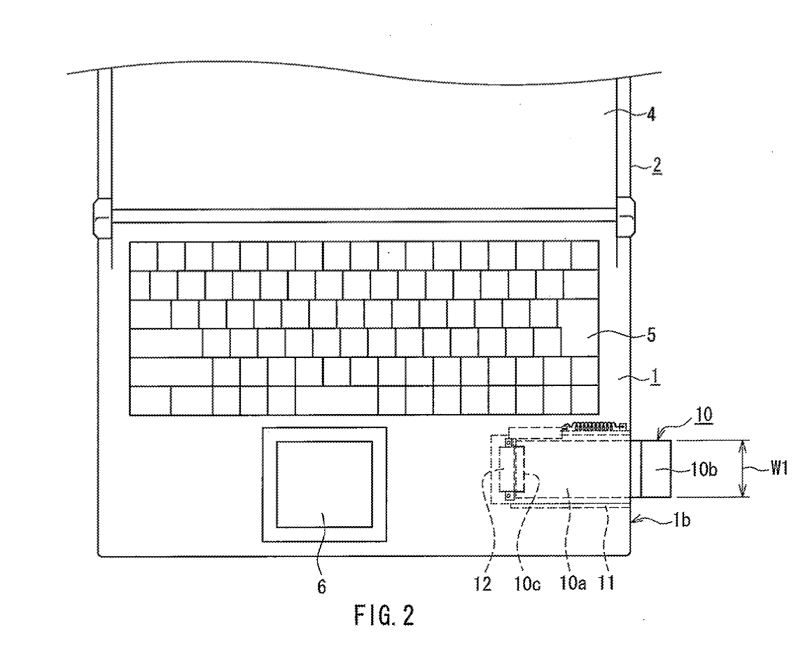

FIG. 1 is a perspective view illustrating an outer appearance of a notebook computer and an expansion card according to the present embodiment. FIG. 2 is a partial plan view of the notebook computer with the expansion card inserted therein. In the present embodiment, although a notebook computer is exemplified as electronic equipment, any equipment at least having a slot allowing an expansion card to be inserted therein or removed therefrom can be used.

As illustrated in FIG. 1, the notebook computer has a first housing 1 and a second housing 2. The first housing 1 contains a circuit board on which various electric elements are mounted, a hard disk drive, and the like. The second housing 2 has a display panel 4. As the display panel 4, for example, a liquid crystal display panel can be used. The first housing 1 and the second housing 2 are supported by hinge parts 3 so as to be opened or closed with respect to each other. The hinge parts 3 have shafts supporting the first housing 1 and the second housing 2 so as to open or close the first housing 1 and the second housing 2 in a direction indicated by an arrow A or B. A keyboard 5 and a pointing device 6 are placed on an upper surface la of the first housing 1. The slot 11 is placed on a side surface lb of the first housing 1. The slot 11 has an opening in a substantially rectangular shape. The expansion card 10 can be inserted in the slot 11.

In the present embodiment, an expansion card having a specification based on the EXPRESS standard is used as an example of the expansion card 10. The expansion card 10 has a thin housing 10a and a thick housing 10b integrated with each other. The thin housing 10a can be inserted in the slot 11 and has an outer dimension (e.g., length: 75 mm, width: 34 mm, thickness: 3.3 mm) based on the EXPRESS standard. At an end of the thin housing 10a, there is a terminal part 10c having a plurality of electrical contact points (e.g., 26 pins). The outer dimension of the thick housing 10b does not largely depend upon the standard, and hence, the thick housing 10b can have various electric circuits, terminals, etc. In the present embodiment, as an example, the thick housing 10b has an antenna capable of being connected to the network wirelessly, a transmission circuit, and a reception circuit.

The slot 11 includes a card holding apparatus capable of holding the expansion card 10. The specific configuration of the card holding apparatus will be described later.

As illustrated in FIG. 2, when the expansion card 10 is inserted in the slot 11, almost the entire thin housing 10a is accommodated in the slot 11. At this time, the thick housing 10b protrudes from the side surface 1b of the first housing 1 without being inserted in the slot 11. The terminal part 10c can be electrically connected to a connector 12 placed in the slot 11.

### [2. Configuration of A Card Holding Apparatus]

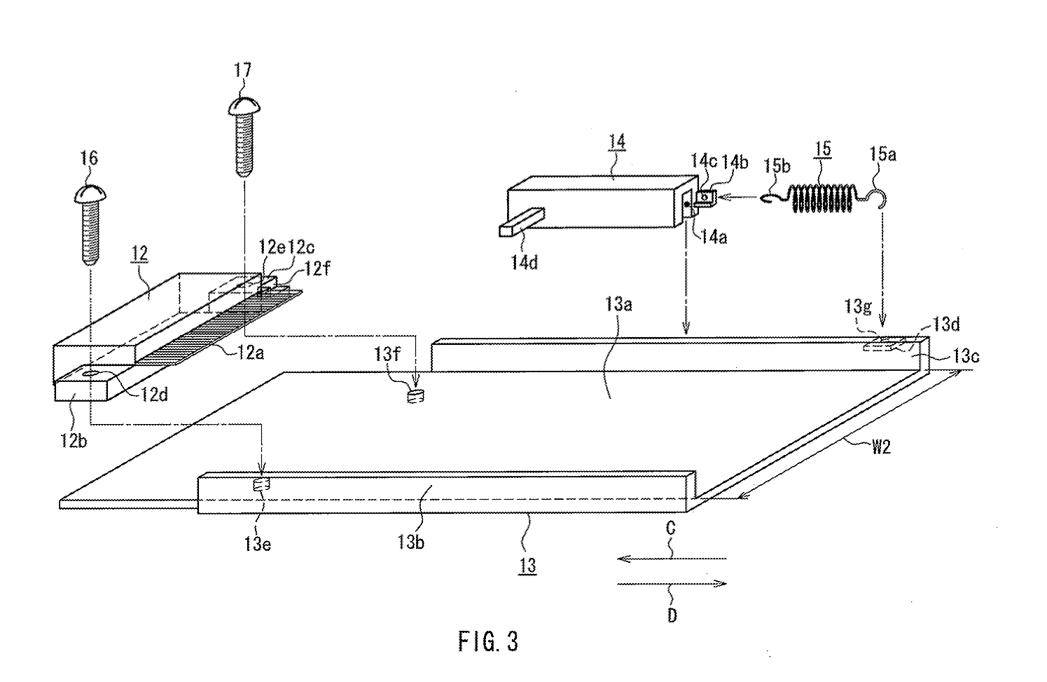

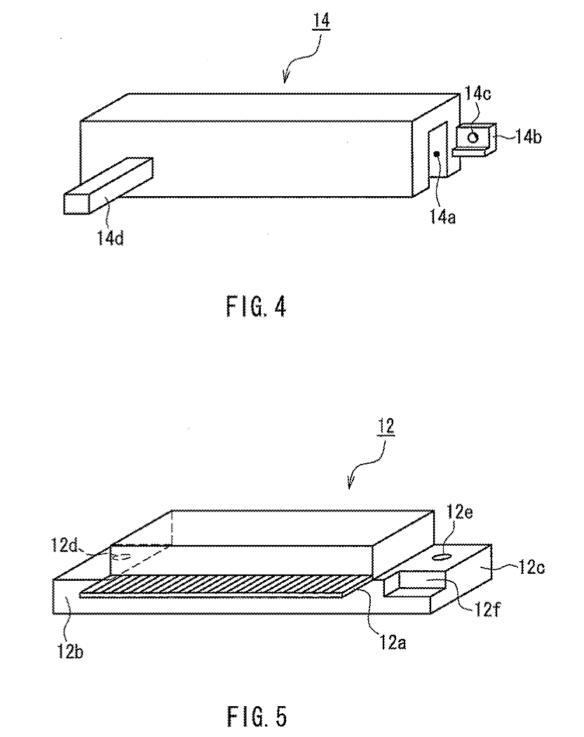

FIG. 3 is an exploded perspective view of the card holding apparatus according to the present embodiment. The card holding apparatus includes the connector 12, a card holder 13, a guide member 14, a spring 15, a screw 16, and a screw 17. FIG. 4 is a perspective view of the guide member 14. FIG. 5 is a perspective view of the connector 12.

The connector 12 has a resin housing substantially in the shape of a rectangular solid, and electric wiring placed in the resin housing. The connector 12 includes a terminal board 12a, a rib 12b, a rib 12c, a hole 12d, a hole 12e, and a regulating part 12f. The terminal board 12a is placed so as to protrude from a first side surface of the connector 12. The terminal board 12a includes a resin substrate and a conductive pattern placed on at least one surface of the resin substrate. The connector 12 includes an opening (not shown) which a flexible printed board (not shown) can be inserted in or removed from, on a second side surface opposed to the first side surface. The rib 12b is formed so as to protrude from a third side surface (adjacent to the first side surface and the second side surface) of the connector 12. The rib 12b is provided with the hole 12d in which the screw 16 can be inserted. The rib 12c is formed so as to protrude from a fourth side surface (opposed to the third side surface) of the connector 12. The rib 12c is provided with a hole 12e in which the screw 17 can be inserted. The rib 12c is provided with the regulating part 12f on a surface directed in the same direction as that of the first side surface of the connector 12. The regulating part 12f is formed in a concave shape so that a protrusion 14d (described later) provided at the guide member 14 can come into contact with the regulating part 12f. The regulating part 12f is not necessarily formed in a concave shape as long as at least the protrusion 14d can come into contact with the regulating part 12f.

A card holder 13 has a bottom 13a, a first side part 13b, and a second side part 13c. The card holder 13 can be formed, for example, by bending a metal plate. It is preferred that the area of a principal plane of the bottom 13a is at least larger than a principal plane of the thin housing 10a of the expansion card 10. The first side part 13b and the second side part 13c are placed on a pair of long sides of the bottom 13a. In the present embodiment, the first side part 13b and the second side part 13c are orthogonal to the principal plane of the bottom 13a. A gap W2 is the one between the first side part 13b and the second side part 13c. The gap W2 is at least larger than a width W1 (see FIG. 2) of the expansion card 10. The bottom 13a is provided with screw holes 13e and 13f.

The guide member 14 has a gap 14a, a rib 14b, a hole 14c, and the protrusion 14d. The guide member 14 can slide along the second side part 13c of the card holder 13. The guide member 14 is provided with a groove in a longitudinal direction (displacement direction), and the groove can be slidably engaged with the second side part 13c. The guide member 14 can be formed, for example, by bending a metal plate. The guide member 14 has the gap 14a capable of sliding with respect to the second side part 13c. The guide member 14 has the rib 14b at one end in the longitudinal direction (displacement direction). The rib 14b is provided with the hole 14c. The guide member 14 is provided with the protrusion 14d in the vicinity of the other end in the longitudinal direction (displacement direction). The protrusion 14d is formed so as to overlap the bottom 13a when the guide member 14 is slid along the second side part 13c. In the present embodiment, although the protrusion 14d is formed substantially in the shape of a rectangular solid, as illustrated in FIG. 4, the shape of the protrusion 14d is not limited thereto.

The spring 15 has a first hook 15a and a second hook 15b. The spring 15 is a coil spring in which an elastic wire is wound in a spiral shape. The first hook 15a is formed at one end of the spring 15. The first hook 15a is engaged with a hole 13g formed in a rib 13d of the card holder 13. The second hook 15b is formed at the other end of the spring 15. The second hook 15b is engaged with the hole 14c formed in the rib 14b of the guide member 14.

The connector 12 can be fixed to the card holder 13 by inserting the screw 16 in the hole 12d and screwing the screw 16 in the screw hole 13e and inserting the screw 17 in the hole 12e and screwing the screw 17 in the screw hole 13f.

The guide member 14 can be displaced in a direction indicated by an arrow C or D along the second side part 13c by engaging the second side part 13c with the gap 14a. When the first hook 15a is engaged with the hole 13g, and the second hook 15b is engaged with the hole 14c, the guide member 14 is held by the card holder 13 while being pulled in the direction indicated by the arrow D.

The guide member 14 includes a cam (not shown) in an inner wall of the gap 14a. The second side part 13c of the card holder 13 is provided with a cam groove (not shown) along which the cam of the guide member 14 can slide. The cam provided in the guide member 14 and the cam groove provided in the card holder 13 realize a heart-shaped cam mechanism as disclosed by, for example, JP 2007-12550 A. Thus, when the guide member 14 is displaced to a predetermined position on the connector 12 side along the second side part 13c, the heart-shaped cam mechanism is locked, which regulates the displacement in the directions indicated by the arrows C and D. Further, when the guide member 14 is displaced further to the connector 12 side from the position where the heart cam mechanism is locked, the lock state of the heart-shaped cam mechanism is cancelled, which enables the displacement in the direction indicated by the arrow D.

Hereinafter, an operation of the card holding apparatus will be described.

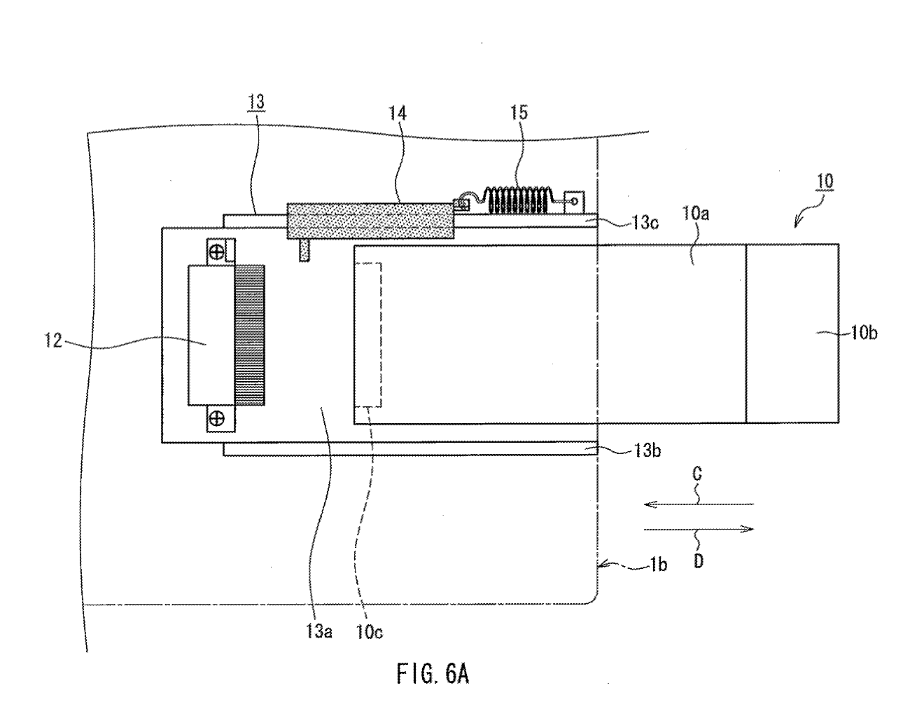

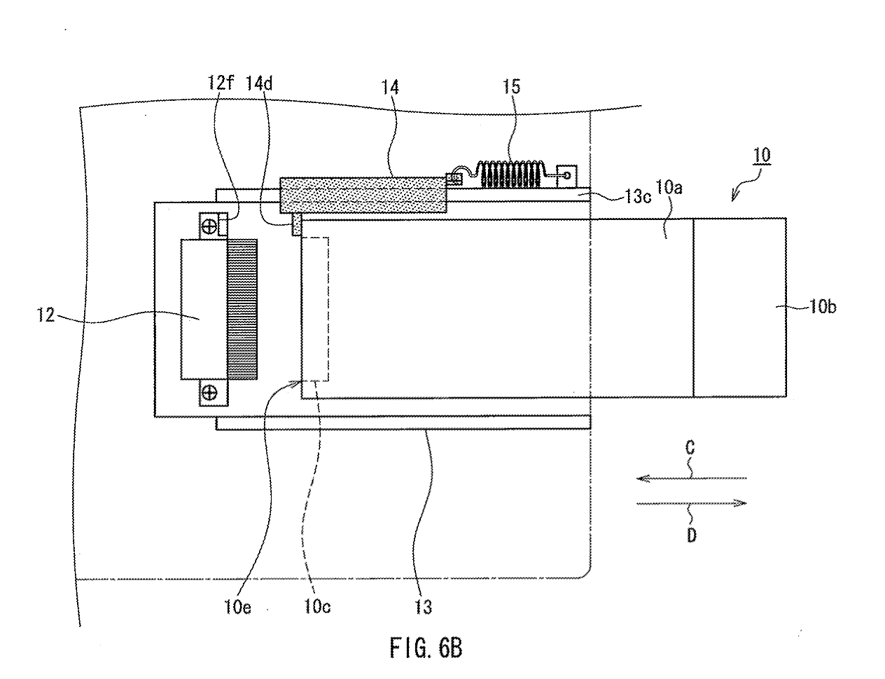

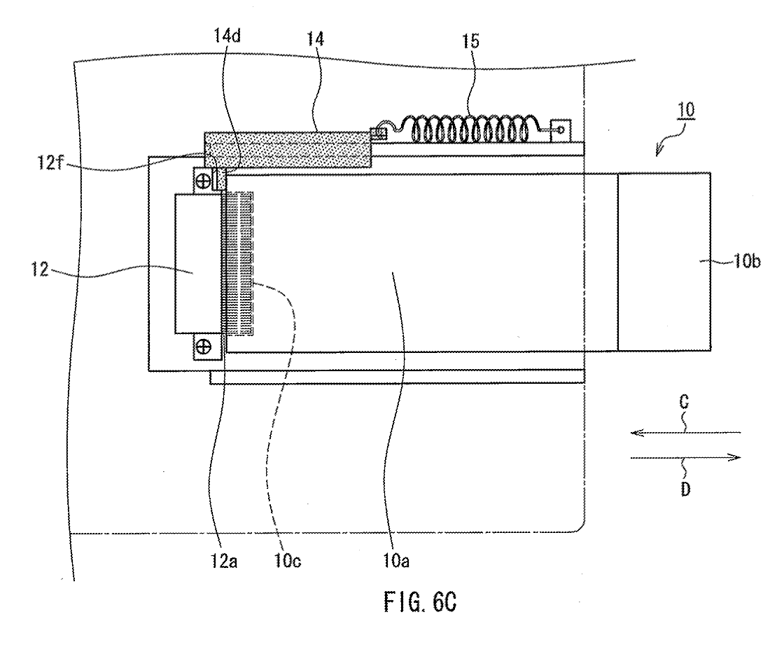

FIGS. 6A to 6C are plan views of the card holding apparatus and the expansion card 10.

First, as illustrated in FIG. 6A, before the expansion card 10 is attached to the card holding apparatus, the guide member 14 is biased in the direction indicated by the arrow D due to an elastic restoring force of the spring 15 and is placed at a position away from the connector 12.

When a user inserts the expansion card 10 in the card holder 13 in the direction indicated by the arrow C and displaces the expansion card 10 further in the direction indicated by the arrow C from the position illustrated in FIG. 6A, an end 10e of the expansion card 10 comes into contact with the protrusion 14d of the guide member 14 as illustrated in FIG. 6B.

When the user displaces the expansion card 10 further in the direction indicated by the arrow C from the position illustrated in FIG. 6B, the protrusion 14d is pushed by the expansion card 10 and the guide member 14 is displaced in the direction indicated by the arrow C along the second side part 13c. At this time, the guide member 14 is displaced while stretching the spring 15 against the elastic restoring force of the spring 15 in the direction indicated by the arrow D.

As illustrated in FIG. 6C, when the user displaces the expansion card 10 to a position where the terminal board 12a of the connector 12 is inserted in the terminal part 10c, a heart-shaped cam mechanism (not shown) provided in the second side part 13c and the guide member 14 is locked. This positions the guide member 14 at a place illustrated in FIG. 6C. At this time, the terminal part 10c and the terminal board 12a are connected electrically.

The protrusion 14d has a gap between the connector 12 and the regulating part 12f. The gap between the protrusion 14d and the regulating part 12f corresponds to a distance in which the lock state of the heart-shaped cam mechanism (not shown) is cancelled when the user pushes the expansion card 10 attached to the card holding apparatus in the direction indicated by the arrow C.

Further, as illustrated in FIG. 6C, when the expansion card 10 is attached to the card holding apparatus, almost the entire thin housing 10a is placed in the card holding apparatus, and the thick housing 10b protrudes from the card holding apparatus and the first housing 1.

In order to detach the expansion card 10 from the card holding apparatus, the user pushes the expansion card 10 in the direction indicated by the arrow C in the state illustrated in FIG. 6C. Specifically, the thick housing 10b is pushed in the direction indicated by the arrow C. When the expansion card 10 is pushed in the direction indicated by the arrow C, the expansion card 10 pushes the protrusion 14d in the direction indicated by the arrow C, and the guide member 14 is slightly displaced in the direction indicated by the arrow C.

When the guide member 14 is displaced in the direction indicated by the arrow C from the position illustrated in FIG. 6C, the lock state of the heart-shaped cam mechanism (not shown) is cancelled. When the lock state of the heart-shaped cam mechanism (not shown) is cancelled, the guide member 14 is displaced in the direction indicated by the arrow D due to the elastic restoring force of the spring 15 in the direction indicated by the arrow D. When the guide member 14 is displaced in the direction indicated by the arrow D, the protrusion 14d pushes the end 10e, and the expansion card 10 is displaced in the direction indicated by the arrow D. The expansion card 10 and the guide member 14 are displaced to the position illustrated in FIG. 6B due to the elastic restoring force of the spring 15. If the elastic restoring force of the spring 15 is strong, the displacement speed of the expansion card 10 and the guide member 14 in the direction indicated by the arrow D increases, and the expansion card 10 may be displaced to the position illustrated in FIG. 6A due to an inertia.

When the user grasps and displaces the thick housing 10b of the expansion card 10 in the direction indicated by the arrow D from the state illustrated in FIG. 6B, the expansion card 10 can be removed from the card holding apparatus and the first housing 1.

Herein, as illustrated in FIG. 6C, when an excess pressure force is applied to the thick housing 10b protruding from the first housing 1 in the direction indicated by the arrow C in the state in which the expansion card 10 is attached to the card holding apparatus, the expansion card 10 and the guide member 14 attempt to be displaced in the direction indicated by the arrow C. At this time, if the pressure force applied to the expansion card 10 is the one capable of deforming the protrusion 14d, the protrusion 14d is supplied with an excess load by the expansion card 10, and attempts to be deformed in the direction indicated by the arrow C. However, the protrusion 14d comes into contact with the regulating part 12f when the protrusion 14d is supplied with an excess load and attempts to be deformed in the direction indicated by the arrow C, due to the presence of the regulating part 12f in the vicinity of the protrusion 14d. This regulates the deformation of the protrusion 14d in the direction indicated by the arrow C, avoiding large deformation and damages. Specifically, the protrusion 14d can be prevented from being deformed largely or damaged to such a degree that the expansion card 10 cannot come into contact with the protrusion 14d when the expansion card 10 is attached thereafter.

Specifically, if an excess pressure force is applied to the expansion card 10 in the direction indicated by the arrow C when a member regulating the deformation of the protrusion 14d is not present on the side of the protrusion 14d indicated by the arrow C, the protrusion 14d may be pushed by the expansion card 10 to be deformed largely or damaged. When the protrusion 14d is deformed largely and damaged, for example, the end 10e of the expansion card 10 cannot come, into contact with the protrusion 14d at a time of the attachment of the expansion card 10 thereafter, and the guide member 14 may not be displaced in the direction indicated by the arrow C. Further, when the protrusion 14d is deformed largely and damaged, for example, the positional relationship between the protrusion 14d and the end 10e is displaced, and the protrusion 14d may interfere with the second side part 13c. Further, when the protrusion 14d is deformed largely and damaged, the sliding part between the gap 14a of the guide member 14 and the second side part 13c is damaged to damage the heart-shaped cam mechanism (not shown), etc. Thus, the guide member 14 may not be displaced in the direction indicated by the arrow C and/or D. Consequently, the heart-shaped cam mechanism (not shown) does not function normally any more, and the expansion card 10 cannot be removed using the elastic restoring force of the spring 15.

Since the connector 12 with the regulating part 12f is fixed firmly to the card holder 13 due to the screws 16 and 17, there is a very low possibility that the connector 12 comes off the card holder 13 even when an excess pressure force is applied to the protrusion 14d and the regulating part 12f.

### [3. Effects of the Embodiment, etc.]

According to the present embodiment, due to the presence of the regulating part 12f in the vicinity of the protrusion 14d of the guide member 14, even when an excess pressure force is applied to the expansion card 10 (see FIG. 6C) attached to the card holding apparatus in the direction indicated by the arrow C, the large deformation of the protrusion 14d can be prevented. Thus, when the subsequent expansion cards 10 are attached, the guide member 14 can be displaced normally in the direction indicated by the arrow C, and the heart-shaped cam mechanism (not shown) can be operated normally. Therefore, the expansion card 10 can be detached from the card holding apparatus using the elastic restoring force of the spring 15.

Further, in the present embodiment, due to the presence of the regulating part 12f regulating the deformation of the protrusion 14d at the connector 12, a member regulating the deformation of the protrusion 14d is not required to be provided as a separate member. Thus, the deformation of the protrusion 14d can be regulated with a smaller number of components. Further, since the connector 12 is firmly fixed to the card holder 13 with the screws 16 and 17, even when an excess pressure force is applied to the expansion card 10, the connector 12 is unlikely to come off the card holder 13.

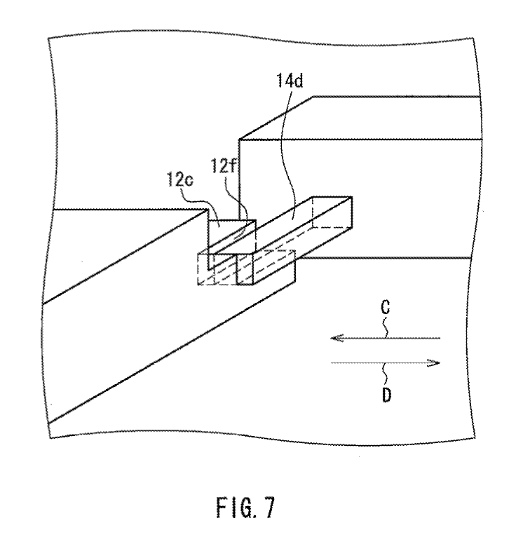

In the present embodiment, although the regulating part 12f is provided in a portion of the connector 12, the present invention is not limited to this configuration. The portion corresponding to the regulating part 12f may be configured so as to come into contact with at least the protrusion 14d. For example, a protrusion rising from the bottom 13a of the card holder 13 in a wall shape may be provided in the vicinity on the side of the arrow C with respect to the protrusion 14d, when the guide member 14 is placed at a position illustrated in FIG. 6C. FIG. 7 is a perspective view illustrating an engagement state between the connector 12 and the guide member 14. In FIG. 7, in order to illustrate the engagement portion between the connector 12 and the guide groove 14, the terminal board 12a (see FIG. 5) and the second side part 13c (see FIGS. 3 and 6, etc.) are not shown. The protrusion 14d can assume a state of being opposed to the regulating part 12f with a minute gap interposed therebetween as illustrated in FIG. 7, and a state in which the protrusion 14d is displaced in the direction indicated by the arrow D from the position illustrated in FIG. 7 to be distant from the regulating part 12f. Since the connector 12 is fixed to the card holder 13, the regulating part 12f does not move from the contact of the protrusion part 14d. In FIG. 7, the configuration is described in which the protrusion 14d is buried in a height direction with respect to the regulating part 12f. However, as long as the protrusion 14d comes into contact with the regulating part 12f, an object can be achieved sufficiently.

Further, in the present embodiment, although one side part (second side part 13c) of the card holder 13 is allowed to hold the guide member 14 and the spring 15, the other side part (first side part 13b) or both the side parts may hold the guide member 14 and the spring 15. In this case, it is preferred that a portion of the guide member 14 held at the first side part 13b has the same structure as that of the protrusion 14d in the present embodiment, and the rib 12b of the connector 12 has the same structure as that of the regulating part 12f in the present embodiment.

Further, in the present embodiment, although the expansion card 10 includes the thin housing 10a and the thick housing 10b, the thick housing 10b is not necessarily required. Even when the expansion card 10 is composed of only the thin housing 10a having a size or shape so that at least a part thereof protrudes from the first housing 1 when the card holding apparatus is attached, the same effects as those of the present embodiment can be obtained. Further, in the case where the expansion card 10 is composed of only the thin housing 10a, even when an excess pressure force is applied to the expansion card when the expansion card is attached to the card holding apparatus, the card holding apparatus can be protected. Thus, it is effective that the expansion card 10 is composed of only the thin housing 10a. Further, any expansion card may be used as long as the expansion card be attached or detached with respect to the card holding apparatus with the heat-shaped cam mechanism.

Further, in the present embodiment, as illustrated in FIG. 6C, the protrusion 14d is prevented from being deformed largely when an excess pressure force is applied to the expansion card 10 from outside in a state where the expansion card 10 is attached to the card holding apparatus. However, even when an excess pressure force is applied to the expansion card 10 from outside in the state illustrated in FIG. 6A or the state illustrated in FIG. 6B, the regulating part 12f can prevent the protrusion 14d from large deformation in the same way as in the present embodiment.

The application of the card holding apparatus in the present embodiment is not limited to a notebook computer, and the card holding apparatus can be applied to any equipment as long as the equipment can be provided with at least a push-pull type card slot. Examples of the equipment of the present embodiment include a desktop personal computer, a memory card reader, a memory card writer, a mobile telephone terminal, a game machine, and an electronic dictionary

Further, the expansion card 10 is not limited to the configuration having an antenna and a transmission/reception circuit as in the present embodiment, and may have another function. For example, the expansion card 10 may contain a storage element capable of writing and reading various information. Further, the expansion card 10 may have a terminal capable of connecting a cable. Examples of the terminal that can be provided at the expansion card 10 include a LAN connector, a terminal based on the Universal Serial Bus (USB) standard, and a terminal based on an Institute of Electrical and Electronic Engineers (IEEE) 1394.

The guide member 14 in the present embodiment is an example of the guide member. The spring 15 in the present embodiment is an example of the biasing member. The regulating part 12f in the present embodiment is an example of the regulating part. The protrusion 14d in the present embodiment is an example of the protrusion. The expansion card 10 in the present embodiment is an example of a card-shaped electronic device.

The present application is useful for a card holding apparatus and electronic equipment.

The invention may be embodied in other forms without departing from the spirit or essential characteristics thereof. The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

What is claimed is:

1. A card holding apparatus allowing an expansion card to be attached or detached with respect thereto, comprising:
a guide member capable of being displaced in an insertion direction and a removal direction of the expansion card;
a biasing member that biases the guide member in the removal direction of the expansion card, wherein
the guide member has a protrusion at a position with which the expansion card is capable of coming into contact, and has a regulating part that is placed on the connector side with respect to the protrusion and regulates a displacement of the protrusion to the connector side.

2. The card holding apparatus according to claim 1, wherein the connector includes the regulating part.

3. Electronic equipment having a slot allowing an expansion card to be inserted therein or removed therefrom, comprising a card holding apparatus that is placed in the slot and allows the expansion card to be attached/detached with respect thereto
wherein the card holding apparatus includes a guide member capable of being displaced in an insertion direction and a removal direction of the expansion card, and a biasing member that biases the guide member in the removal direction of the expansion card, and
the guide member has a protrusion at a position with which the expansion card comes into contact, and a regulating part that is placed on the connector side with respect to the protrusion and regulates a displacement of the protrusion on the connector side.
